(19) United States
(12) Patent Application Publication
(10) Pub. No.: US 2014/0375195 A1
(43) Pub. Date: Dec. 25, 2014

(54) BEZEL ASSEMBLY FOR ELECTRONIC DEVICE

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: LIANG-CHIN WANG, New Taipei (TW); YU-MING XIAO, Wuhan (CN); LIN DING, Wuhan (CN); ZHI-JUN FU, Wuhan (CN)

(73) Assignees: HON HAI PRECISION INDUSTRY CO., LTD., New Taipei (TW); HONG FU JIN PRECISION INDUSTRY (WUHAN) CO., LTD., Wuhan (CN)

(21) Appl. No.: 14/252,135

(22) Filed: Apr. 14, 2014

(30) Foreign Application Priority Data
Jun. 21, 2013 (CN) 2013102490388

(51) Int. Cl. H05K 5/02; H05K 9/00

(52) U.S. Cl. CPC H05K 5/0239; H05K 5/0221; H05K 5/0226; H05K 9/00
USPC 312/326

(57) ABSTRACT

A bezel assembly includes a panel, and a shielding member. The panel includes a main body and two latching structures located on the main body. Each of the two latching structures includes a latching board, and the latching board defines a latching hole and a guiding slot in communication with the latching hole. The shielding member is engaged with the main body and comprises two rotating arms. Each of the two rotating arms is rotatably engaged in the latching hole of each of the two latching structures, and the latching board is resiliently deformable to disengage each of the two rotating arms from the latching hole along the guiding slot.

### FIELD

The present disclosure relates to electronic device enclosures, more particularly to a bezel assembly.

### BACKGROUND

A panel of a computer case may define an opening on a bezel for installing an optical disk drive. A shielding plate is often needed to shield the opening for preventing dust and electro-magnetic interference. However, it is complicated to have an extra mounting structure for securing the shielding plate to the panel. Therefore, an improved bezel assembly is warranted.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. In the drawings, like reference numerals designate corresponding parts throughout the several views.

FIG. 1 is an exploded, cutaway view of a bezel assembly in accordance with an embodiment of the disclosure.

FIG. 2 is similar to FIG. 1, but showing from another aspect.

FIG. 3 is an enlarged view of a circled portion II of FIG. 2.

FIG. 4 is an assembled view of the bezel assembly of FIG. 2, and a shielding board is located in a closed position.

FIG. 5 is another assembled view of the bezel assembly of FIG. 2, and the shielding board is located in an open position.

FIG. 6 is a similar to FIG. 4, but is the assembled view from a different perspective.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

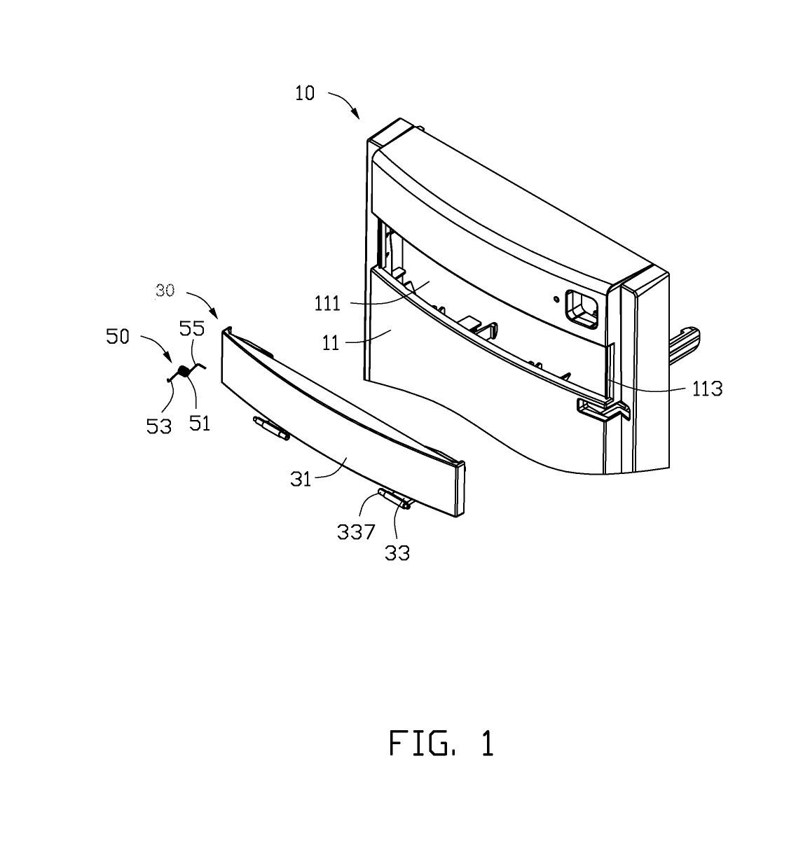

FIGS. 1-3 show a bezel assembly in accordance with an embodiment including a panel 10, a shielding member 30, and a resilient member 50 installed between the panel 10 and the shielding member 30. In at least one embodiment, the panel 10 is a decorating panel of a computer case, and the resilient member 50 is a torsion spring.

In the embodiment shown in FIG. 1, the resilient member 50 includes a spring coil 51, a first engaging leg 53, and a second engaging leg 55. The first engaging leg 53 and the second engaging leg 55 extend towards two opposite directions from two opposite ends of the spring coil 51.

FIGS .1 and 2 show that, the panel 10 includes a main body 11 and two latching structures 15 located on the main body 11. The main body 11 defines an opening 111 for receiving an optical disk drive (not shown), and a strip 113 extends towards the shielding member 30 from two opposite edges of the opening 111. The two latching structures 15 are symmetrically located on a back surface of the main body 11 and arranged below the opening 111. In other embodiments, the panel 10 only includes one latching structure 15.

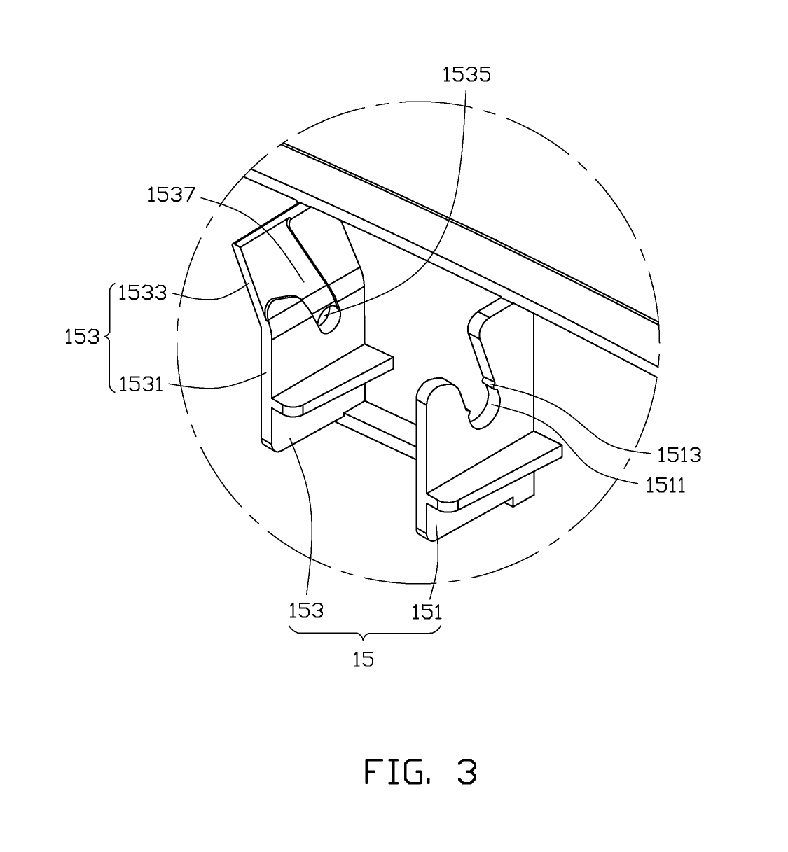

In the embodiment shown in FIG. 3 shows that, each of the two latching structures 15 includes a limiting board 151 and a latching board 153 opposite to the limiting board 151. The limiting board 151 extends outwards from the main body 11 and defines a limiting slot 1511. A rib 1513 extends from two opposite edges of the limiting slot 1511. In one embodiment, the limiting board 151 is substantially perpendicular to the main body 11, and the limiting slot 1511 is substantially U-shaped. The latching board 153 extends outwards from the main body 11 and includes a first latching piece 1531 and a second latching piece1533 integrated with the first latching piece 1531. The first latching piece 1531 defines a latching hole 1535 adjacent to the second latching piece 1533. The second latching piece 1533 obliquely extends from the first latching piece 1531 and defines a guiding slot 1537 in one side surface of the second latching piece 1533. The guiding slot 1537 is in communication with the latching hole 1535 and aligned with the limiting slot 1511. In one embodiment, an obtuse angle is defined between the first latching piece 1531 and the second latching piece 1533, and the guiding slot 1537 is substantially U-shaped.

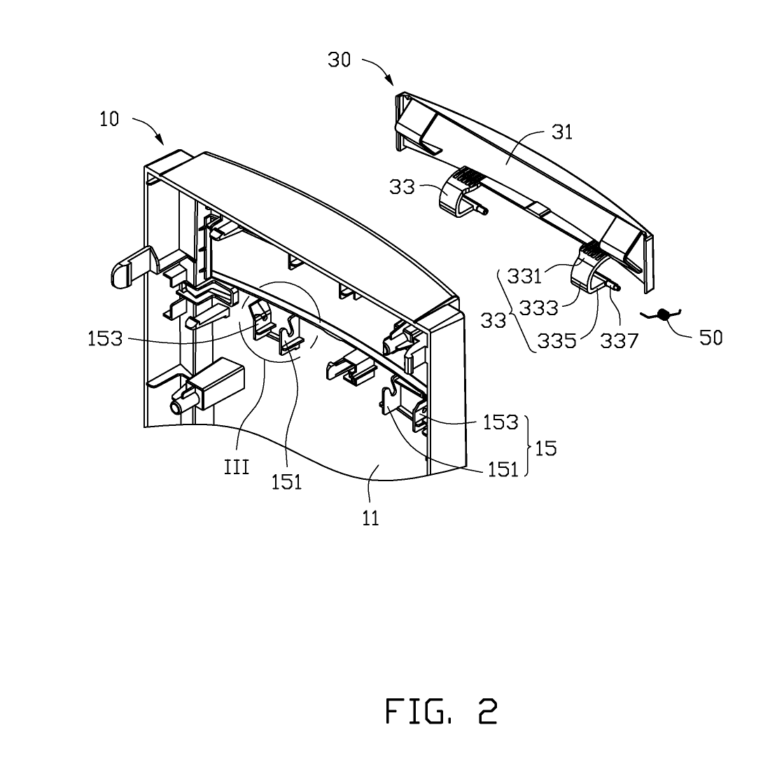

FIG. 2 illustrates that the shielding member 30 includes a shielding board 31, and two rotating arms 33. The shielding board 31 covers the opening 111. Each of the two rotating arms 33 is located on the shielding board 31 and includes a connecting piece 331, a bending piece 333, and a linking piece 335. The connecting piece 331 extends outwards from a bottom edge of the shielding board 31. The bending piece 333 bends from a distal end of the connecting piece 331. The linking piece 335 extends towards the shielding board 31 from the bending piece 333 and located below the connecting piece 331. A rotating shaft 337 is located on the linking piece 335. In one embodiment, each of the two rotating arms 33 is substantially U-shaped, and a length of the rotating shaft 337 is slightly greater than a distance between the limiting board 151 and the first latching piece 1531.

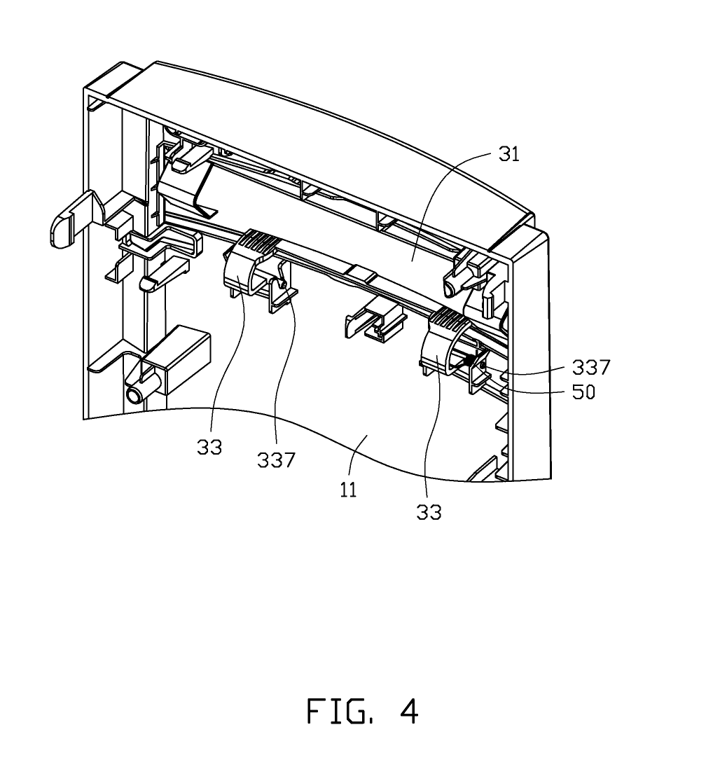

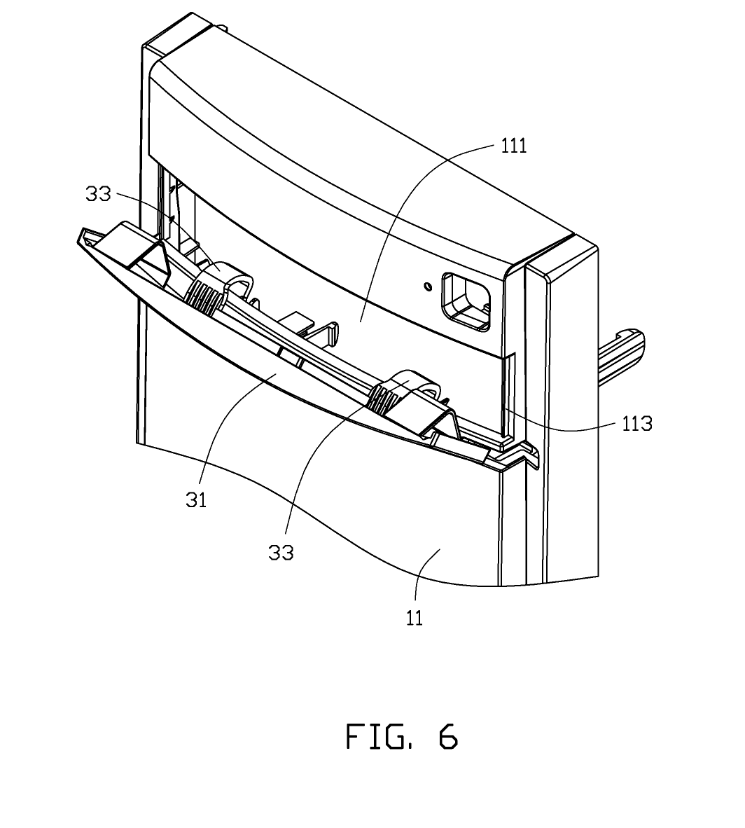

FIGS. 1-6 illustrate that, in assembly, the resilient member 50 suspends on the rotating shaft 337 via the spring coil 51 surrounding on the rotating shaft 337. The two rotating arms 33 extend through the opening 111 from the front side of the panel 10, and each of the two rotating arms 33 is aligned with each of the two latching structures 15. A first end of the rotating shaft 337 is inserted into the limiting slot 1511, and a second end opposite to the first end of the rotating shaft 337 is slid into the guiding slot 1537. The two rotating arms 33 are pressed downwards, and the rotating shaft 337 resists and deforms the latching board 153, until the second end of the rotating shaft 337 is aligned with the latching hole 1535. The latching board 153 resiliently rounds to the latching hole 1535 receiving the second end of the rotating shaft 337. The ribs 1513 limit the second end of the rotating shaft 337 preventing the rotating shaft 337 from disengaging from the limiting slot 1511. The first engaging leg 53 is engaged with corresponding rotating arm 33, and the second engaging leg 55 is engaged with the main body 11. Therefore, the resilient member 50 has twisting force to position the shielding member 30 in a closed position (shown in FIG. 4), where the shielding member 30 covers the opening 111.

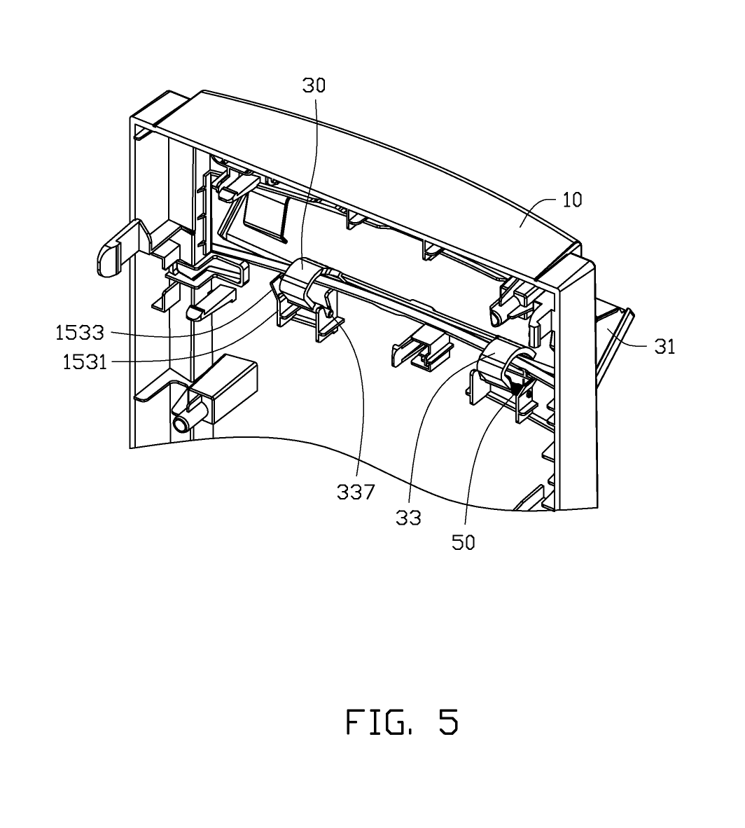

In use, the optical disk drive pushes the shielding board 31, the shielding board 31 is rotated along a first direction, until the shielding board 31 is located in an open position (shown in FIG. 5). The optical disk drive is therefore exposed out of the panel 10.

When detaching the shielding member 30, the latching board 153 is pulled outward to disengage the rotating shaft 337 from the latching hole 1535. Simultaneously, the shielding member 30 is pulled upwards, and the rotating shaft 337 is slid out of corresponding latching structure 15 along the guiding slot 1537. Therefore, the shielding member 30 is detached from the panel 10.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A bezel assembly comprising:
a panel comprising a main body and a latching structure located on the main body, the latching structure comprising a latching board, and a limiting board opposite to the latching board, and the latching board defining a latching hole and a guiding slot in communication with the latching hole; and
a shielding member engaged with the main body and comprising a rotating arm located between the latching board and the limiting board;
wherein the rotating arm is rotatably engaged in the latching hole, and the latching board is resiliently deformable to disengage the rotating arm from the latching hole along the guiding slot.

2. The bezel assembly of claim 1, wherein the latching board comprises a first latching piece and a second latching piece extending from the first latching piece, the latching hole is defined in the first latching piece, and the guiding slot is defined in the second latching piece.

3. The bezel assembly of claim 2, wherein an obtuse angle is defined between the first latching piece and the second latching piece.

4. The bezel assembly of claim 2, wherein the limiting board defines a limiting slot, the rotating arm comprises a rotating shaft, and the rotating shaft is engaged in the latching hole and the limiting slot, and the latching board is resiliently deformable along a direction that is parallel to an center axis of the rotating shaft, to disengage the rotating shaft from the latching hole and the limiting hole.

5. The bezel assembly of claim 4, wherein the limiting board and the first latching piece are parallel to each other and perpendicularly connected to the main body.

6. The bezel assembly of claim 4, wherein the limiting slot is substantially U-shaped and aligned with the guiding slot.

7. The bezel assembly of claim 4, wherein a rib extends from opposites edges of the limiting slot, and the rib abuts the rotating shaft.

8. The bezel assembly of claim 4, wherein the shielding member further comprises a shielding board, the panel defines an opening, and the shielding board covers the opening, and is rotatable about the rotating shaft to open the opening.

9. The bezel assembly of claim 8, wherein the two rotating arms further comprise a connecting piece, a bending piece, and a linking piece, the connecting piece extends from the shielding board, the bending piece extends from the connecting piece, and the linking piece extends from the bending pieces, and the rotating shaft is located in the linking piece.

10. The bezel assembly of claim 8, further comprising a resilient member, wherein the resilient member surrounds the rotating shaft and is engaged between the one of the two rotating arms and the main body.

11. A bezel assembly comprising:
a panel comprising a main body and two latching structures located on the main body, each of the two latching structures comprising a latching board, and the latching board defining a latching hole and a guiding slot in communication with the latching hole; and
a shielding member engaged with the main body and comprising two rotating arms; and
wherein each of the two rotating arms is rotatably engaged in the latching hole of each of the two latching structures, and the latching board is resiliently deformable to disengage each of the two rotating arms from the latching hole along the guiding slot.

12. The bezel assembly of claim 11, wherein the latching board comprises a first latching piece and a second latching piece extending from the first latching piece, the latching hole is defined in the first latching piece, and the guiding slot is defined in the second latching piece.

13. The bezel assembly of claim 12, wherein an obtuse angle is defined between the first latching piece and the second latching piece.

14. The bezel assembly of claim 12, wherein each of the two latching structures further comprises a limiting board, the limiting board defines a limiting slot, each of the two rotating arms comprises a rotating shaft, and the rotating shaft is engaged in the latching hole and the limiting slot, and the latching board is resiliently deformable along a first direction that is parallel to an center axis of the rotating shaft, to disengage the rotating shaft from the latching hole.

15. The bezel assembly of claim 14, wherein the limiting board and the first latching piece are parallel to each other and perpendicularly connected to the main body.

16. The bezel assembly of claim 14, wherein a rib extends from opposites edges of the limiting slot, and the rib abuts the rotating shaft.

17. The bezel assembly of claim 14, wherein the shielding member further comprises a shielding board, the panel defines an opening, and the shielding board covers the opening, and is rotatable about the rotating shaft to open the opening.

18. The bezel assembly of claim 17, wherein each of the two rotating arms further comprise a connecting piece, a bending piece, and a linking piece, the connecting piece extends from the shielding board, the bending piece extends from the connecting piece, and the linking piece extends from the bending pieces, and the rotating shaft is located in the linking piece.

19. The bezel assembly of claim 18, further comprising a resilient member, wherein the resilient member surrounds the rotating shaft and is engaged between the one of the two rotating arms and the main body.

20. The bezel assembly of claim 14, wherein a length of the rotating shaft is slightly greater than a distance between the limiting board and the first latching piece.
